(19) United States
(12) Patent Application Publication
(10) Pub. No.: US 2024/0222554 A1
(43) Pub. Date: Jul. 4, 2024

(54) LIGHT EMITTING ELEMENT AND METHOD OF MANUFACTURING LIGHT EMITTING ELEMENT

(71) Applicant: Samsung Display Co., LTD., Yongin-si (KR)

(72) Inventors: Hyung Rae CHA, Yongin-si (KR); Hoo Keun PARK, Yongin-si (KR); Dong Uk KIM, Yongin-si (KR)

(73) Assignee: Samsung Display Co., LTD., Yongin-si (KR)

(21) Appl. No.: 18/517,315

(22) Filed: Nov. 22, 2023

(30) Foreign Application Priority Data
Jan. 2, 2023 (KR) 10-2023-0000446

(51) Int. Cl. H01L 33/24; H01L 33/10; H01L 33/38

(52) U.S. Cl. CPC H01L 33/24; H01L 33/10; H01L 33/38

(57) ABSTRACT

A light emitting element includes a first semiconductor layer, a second semiconductor layer, an active layer between the first semiconductor layer and the second semiconductor layer, and a first insulating layer surrounding the first semiconductor layer, the second semiconductor layer, and the active layer, and a first thickness of the first insulating layer surrounding the first semiconductor layer is different from a second thickness of the first insulating layer surrounding the second semiconductor layer.

### CROSS REFERENCE TO RELATED APPLICATION(S)

This application claims priority to and benefits of Korean Patent Application No. 10-2023-0000446 under 35 U.S.C. § 119, filed on Jan. 2, 2023, the entire contents of which are incorporated herein by reference.

### BACKGROUND

### 1. Technical Field

Embodiments relate to a light emitting element and a method of manufacturing the light emitting element.

### 2. Description of the Related Art

In recent years, as interest in information display has increased, research and development for a display device have been continuously conducted.

### SUMMARY

Embodiments provide a light emitting element and a method of manufacturing the light emitting element capable of minimizing a surface defect.

However, embodiments of the disclosure are not limited to those set forth herein. The above and other embodiments will become more apparent to one of ordinary skill in the art to which the disclosure pertains by referencing the detailed description of the disclosure given below.

According to an embodiment, a light emitting element may include a first semiconductor layer, a second semiconductor layer, an active layer between the first semiconductor layer and the second semiconductor layer, and a first insulating layer surrounding the first semiconductor layer, the second semiconductor layer, and the active layer, and a first thickness of the first insulating layer surrounding the first semiconductor layer may be different from a second thickness of the first insulating layer surrounding the second semiconductor layer.

The first thickness of the first insulating layer may be thinner than the second thickness of the first insulating layer.

A diameter of the first semiconductor layer and a diameter of the second semiconductor layer may be same as each other.

A diameter of the first semiconductor layer may be greater than a diameter of the second semiconductor layer.

The light emitting element may further include a second insulating layer surrounding the first insulating layer.

The light emitting element may further include an electrode layer disposed on the first semiconductor layer and the first insulating layer.

The second insulating layer may surround a side surface of the electrode layer.

The second insulating layer may expose the electrode layer and the second semiconductor layer.

The light emitting element may further include a reflective layer disposed on the second insulating layer.

According to an embodiment for solving the above-described object, a method of manufacturing a light emitting element may include forming a first insulating layer on a stack substrate, forming an opening by etching the first insulating layer, forming a first semiconductor layer, an active layer, and a second semiconductor layer in the opening of the first insulating layer, partially etching the first insulating layer in a first area, and forming a second insulating layer surrounding the first insulating layer in a second area, and in the etching of the first insulating layer in the first area, a thickness of the first insulating layer surrounding the first semiconductor layer may be thinner than a thickness of the first insulating layer surrounding the second semiconductor layer.

The method may further include forming an electrode layer on the first semiconductor layer and the first insulating layer.

The method may further include etching the electrode layer in the first area.

The electrode layer and the first insulating layer in the first area may be simultaneously etched.

The second insulating layer may surround the electrode layer in the second area.

A surface of the electrode layer may be exposed by partially etching the second insulating layer.

A diameter of a first end portion of the opening may be the same as a diameter of a second end portion of the opening.

A diameter of a first end portion of the opening may be greater than a diameter of a second end portion of the opening.

The first semiconductor layer may be formed at the first end portion of the opening, and the second semiconductor layer may be formed at the second end portion of the opening.

The method may further include forming a reflective layer on the second insulating layer.

The method may further include separating the second semiconductor layer from the stack substrate.

Details of other embodiments are included in the detailed description and drawings.

According to the above-described embodiment, the light emitting element may be formed by partially etching the first insulating layer after forming the first semiconductor layer, the active layer, and/or the second semiconductor layer in the opening of the first insulating layer. Therefore, a surface defect may be minimized, and thus a lifespan and light emission efficiency of the light emitting elements may be improved.

An effect according to embodiments is not limited by the contents illustrated above, and more various effects are included in the description.

### BRIEF DESCRIPTION OF THE DRAWINGS

The above and other features of the disclosure will become more apparent by describing in further detail embodiments thereof with reference to the accompanying drawings, in which:

FIGS. 1 to 3 are schematic cross-sectional views illustrating a light emitting element according to an embodiment;

FIGS. 4 to 12 are schematic cross-sectional views for each process step of a method of manufacturing a light emitting element according to an embodiment;

FIGS. 13 and 14 are schematic cross-sectional views for each process step of a method of manufacturing a light emitting element according to an embodiment;

FIGS. 15 to 22 are schematic cross-sectional views for each process step of a method of manufacturing a light emitting element according to an embodiment; and

FIGS. 23 and 24 are schematic cross-sectional views illustrating a display device according to an embodiment.

### DETAILED DESCRIPTION OF THE EMBODIMENT

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated clements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only. Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments of the disclosure are described in detail with reference to the accompanying drawings.

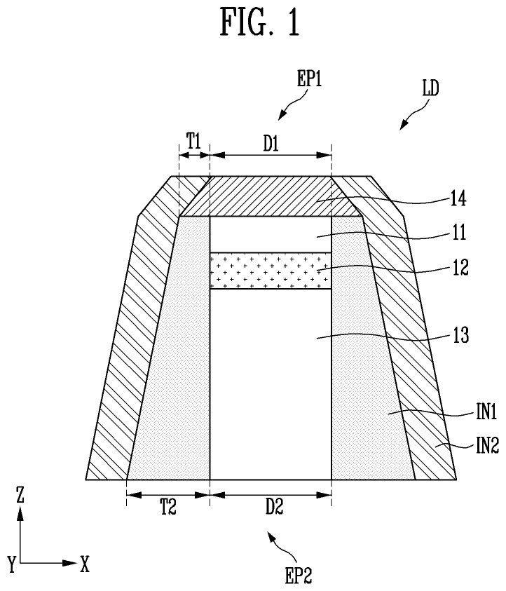

FIGS. 1 to 3 are schematic cross-sectional views illustrating a light emitting element according to an embodiment. FIGS. 1 to 3 show a column-shaped light emitting element LD, but a type and/or a shape of the light emitting element LD are/is not limited thereto.

Referring to FIGS. 1 to 3, the light emitting element LD may include a first semiconductor layer 11, an active layer 12, a second semiconductor layer 13, an electrode layer 14, a first insulating layer IN1, and/or a second insulating layer IN2.

The light emitting element LD may be formed in a column shape extending along a third direction (e.g., Z-axis direction). The light emitting element LD may have a first end portion EP1 and a second end portion EP2. In an embodiment, a diameter of the first end portion EP1 and a diameter of the second end portion EP2 of the light emitting element LD may be different from each other. For example, the diameter of the first end portion EP1 of the light emitting element LD may be less than the diameter of the second end portion EP2, but embodiments are not limited thereto.

One of the first and second semiconductor layers 11 and 13 may be disposed at the first end portion EPI of the light emitting element LD. The other of the first and second semiconductor layers 11 and 13 may be disposed at the second end portion EP2 of the light emitting element LD. For example, the first semiconductor layer 11 may be disposed at the first end portion EP1 of the light emitting element LD, and the second semiconductor layer 13 may be disposed at the second end portion EP2 of the light emitting element LD.

According to an embodiment, the light emitting element LD may be a light emitting clement manufactured in a column shape by a growth method/process or the like. In the description, the column shape may include a rod-like shape or a bar-like shape of which an aspect ratio is greater than 1, such as a circular column or a polygonal column, and the shape of the cross section thereof is not limited thereto.

The light emitting element LD may have a size as small as a nanometer scale to a micrometer scale. For example, each light emitting element LD may have a diameter (or width) and/or a length of a nanometer scale to micrometer scale range. However, a size of the light emitting element LD is not limited thereto, and the size of the light emitting element LD may be variously changed according to a design condition of various devices including a light emitting device (e.g., the light emitting element LD) as a light source, for example, a display device or the like.

The first semiconductor layer 11 may be a semiconductor layer of a first conductivity type. For example, the first semiconductor layer 11 may include a p-type semiconductor layer. For example, the first semiconductor layer 11 may include at least one semiconductor material among InAlGaN, GaN, AlGaN, InGaN, or AIN, and may include a p-type semiconductor layer doped with a first conductivity type dopant such as Mg. However, a material of the first semiconductor layer 11 is not limited thereto, and the first semiconductor layer 11 may be formed of various other materials.

The active layer 12 may be disposed between the first semiconductor layer 11 and the second semiconductor layer 13. The active layer 12 may include any one of a single well structure, a multi well structure, a single quantum well structure, a multi quantum well (MQW) structure, a quantum dot structure, or a quantum wire structure, but embodiments are not limited thereto. The active layer 12 may include GaN, InGaN, InAlGaN, AlGaN, or AIN, and the active layer 12 may be formed of various other materials.

In case that a voltage equal to or greater than a threshold voltage is applied to both end portions of the light emitting element LD, an electron-hole pair is combined in the active layer 12 and thus the light emitting element LD may emit light. By controlling emission of the light emitting element LD, the light emitting element LD may be used as a light source of various light emitting devices including a pixel of a display device.

The second semiconductor layer 13 may be disposed on the active layer 12 and may include a semiconductor layer of a type different from that of the first semiconductor layer 11. The second semiconductor layer 13 may include an n-type semiconductor layer. For example, the second semiconductor layer 13 may include any one semiconductor material among InAlGaN, GaN, AlGaN, InGaN, and AIN, and may include an n-type semiconductor layer doped with a second conductivity type dopant such as Si, Ge, and Sn. However, a material of the second semiconductor layer 13 is not limited thereto, and the second semiconductor layer 13 may be formed of various other materials.

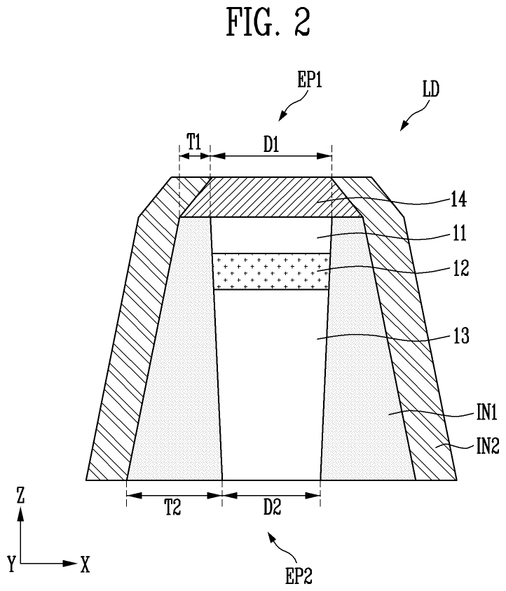

As shown in FIG. 1, a diameter D1 of the first semiconductor layer 11 and a diameter D2 of the second semiconductor layer 13 may be the same as each other. However, embodiments are not limited thereto, and as shown in FIG. 2, the diameter D1 of the first semiconductor layer 11 may be different from the diameter D2 of the second semiconductor layer 13. For example, the diameter D1 of the first semiconductor layer 11 may be greater than the diameter D2 of the second semiconductor layer 13, but embodiments are not limited thereto.

The first insulating layer IN1 may surround the first semiconductor layer 11, the active layer 12, and/or the second semiconductor layer 13. For example, the first insulating layer IN1 may be disposed (e.g., directly disposed) on a surface of the first semiconductor layer 11, the active layer 12, and/or the second semiconductor layer 13.

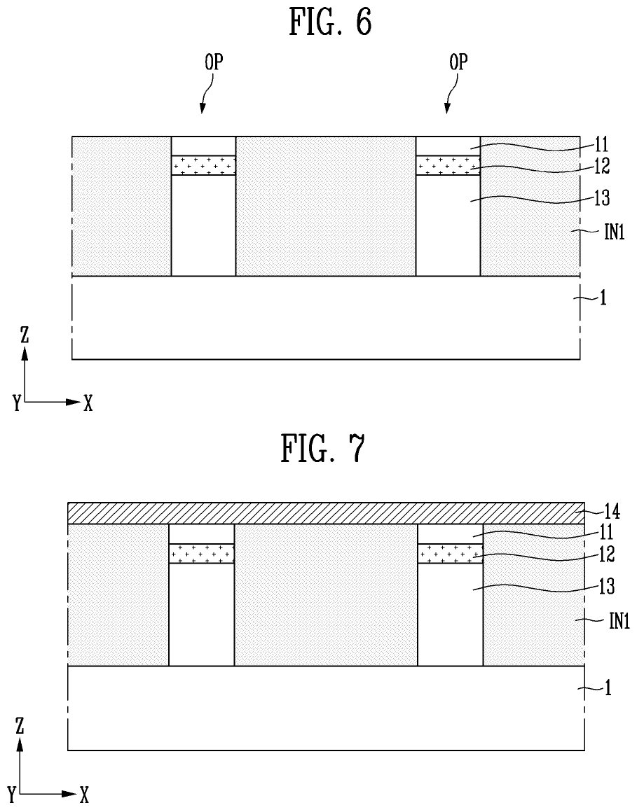

In an embodiment, the first insulating layer IN1 may function as a structure for growth of the active layer 12 and/or the second semiconductor layer 13. The first insulating layer IN1 may minimize a surface defect of the light emitting elements LD to improve a lifespan and light emission efficiency of the light emitting elements LD. For example, the first semiconductor layer 11, the active layer 12, and/or the second semiconductor layer 13 may be formed in an opening of the first insulating layer IN1. A detailed description thereof is described below with reference to FIG. 6.

The first insulating layer IN1 may expose the first and second end portions EP1 and EP2 of the light emitting element LD. According to an embodiment, the first insulating layer IN1 may expose a surface of the first semiconductor layer 11 and/or the second semiconductor layer 13 adjacent to the first and second end portions EP1 and EP2 of the light emitting element LD.

The first insulating layer IN1 may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ). For example, the first insulating layer IN1 may be formed as double layers, and each layer of the double layers may include different materials. For example, the first insulating layer IN1 may be formed as double layers formed of aluminum oxide (AlOₓ) and silicon oxide (SiOₓ), but embodiments are not limited thereto. For example, the first insulating layer IN1 may be formed of a high dielectric constant material. For example, a dielectric constant of the first insulating layer IN1 may be 10 or more, but embodiments are not limited thereto.

A first thickness T1 of the first insulating layer IN1 surrounding the first semiconductor layer 11 may be different from a second thickness T2 of the first insulating layer IN1 surrounding the second semiconductor layer 13. For example, the first thickness T1 of the first insulating layer IN1 surrounding the first semiconductor layer 11 may be thinner than the second thickness T2 of the first insulating layer IN1 surrounding the second semiconductor layer 13. As described above, as the first thickness T1 of the first insulating layer IN1 is formed to be thinner than the second thickness T2 of the first insulating layer IN1, the diameter of the first end portion EP1 of the light emitting element LD may be formed to be less than the diameter of the second end portion EP2 of the light emitting element LD. For example, a cross section of the light emitting element LD may have a trapezoidal shape, but embodiments are not limited thereto.

The electrode layer 14 may be disposed on the first end portion EP1 and/or the first insulating layer IN1 of the light emitting element LD. For example, the electrode layer 14 may be disposed on the first semiconductor layer 11 and the first insulating layer IN1. However, embodiments are not limited thereto, and a separate electrode layer may be further disposed on the second end portion EP2 (or the second semiconductor layer 13) of the light emitting element LD.

According to an embodiment, a cross section of the electrode layer 14 may be formed in a trapezoidal shape. For example, a surface of the electrode layer 14 adjacent to the first end portion EP1 may be narrower than another surface of the electrode layer 14 adjacent to the second end portion EP2. However, embodiments are not limited thereto, and the surface and another surface of the electrode layer 14 may be formed identically.

The electrode layer 14 may include a transparent metal or a transparent metal oxide. For example, the electrode layer 14 may include at least one of indium tin oxide (ITO), indium zinc oxide (IZO), and zinc tin oxide (ZTO), but embodiments are not limited thereto. As described above, in case that the electrode layer 14 is formed of the transparent metal or the transparent metal oxide, light generated in the active layer 12 of the light emitting element LD may pass through the electrode layer 14 and may be emitted to an outside of the light emitting element LD.

The second insulating layer IN2 may surround the first insulating layer IN1 and/or the electrode layer 14. For example, the second insulating layer IN2 may be disposed (e.g., directly disposed) on a surface of the first insulating layer IN1 and/or the electrode layer 14. The second insulating layer IN2 may expose the first and second end portions EP1 and EP2 of the light emitting element LD. For example, the second insulating layer IN2 may expose a surface of the electrode layer 14 and/or the second semiconductor layer 13. For example, the second insulating layer IN2 may expose a surface of the electrode layer 14 and may surround a side surface of the electrode layer 14. The second insulating layer IN2 may minimize the surface defect of the light emitting elements LD to improve the lifespan and the light emission efficiency of the light emitting elements LD.

The second insulating layer IN2 may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ). For example, the second insulating layer IN2 may be formed as double layers, and each layer formed as the double layers may include different materials. For example, the second insulating layer IN2 may be formed as double layers formed of aluminum oxide (AlOₓ) and silicon oxide (SiOₓ), but embodiments are not limited thereto. For example, the second insulating layer IN2 may be formed in a substantially uniform/constant thickness, but embodiments are not limited thereto.

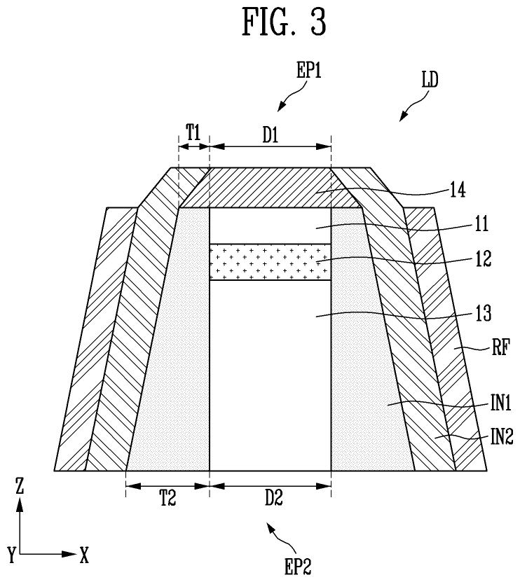

As shown in FIG. 3, the light emitting element LD may further include a reflective layer RF disposed on the second insulating layer IN2. The reflective layer RF may be disposed (e.g., directly disposed) on the second insulating layer IN2. The reflective layer RF may be disposed on a side surface of the light emitting element LD, and may expose the first end portion EP1 and the second end portion EP2 of the light emitting element LD. The reflective layer RF may improve light output efficiency by reflecting light emitted from the active layer 12. For example, as described above, in case that the first thickness T1 and the second thickness T2 of the first insulating layer IN1 are formed differently, a cross section of the light emitting element LD may be formed in a trapezoidal shape, and thus the reflective layer RF may be formed in an inclined shape. Therefore, since the light emitted from the active layer 12 is reflected by the reflective layer RF and emitted in a front surface direction of a display panel, the light output efficiency may be increased or improved. A material of the reflective layer RF is not limited, and the reflective layer RF may be formed of various reflective materials. For example, the reflective layer RF may be formed of distributed Bragg reflectors (DBR) in which a plurality of layers having different refractive indices are alternately stacked, but embodiments are not limited thereto. A reflectance of the reflective layer RF formed of the DBR may be about 80% or more, but embodiments are not limited thereto.

A light emitting device including the light emitting element LD described above may be used in various types of devices that require a light source and include a display device. For example, the light emitting elements LD may be disposed in each pixel of a display panel, and the light emitting elements LD may be used as a light source of each pixel. However, an application field of the light emitting element LD is not limited to the above-described example. For example, the light emitting clement LD may also be used in other types of devices that require a light source, such as a lighting device.

A method of manufacturing the light emitting element according to the above-described embodiments is described.

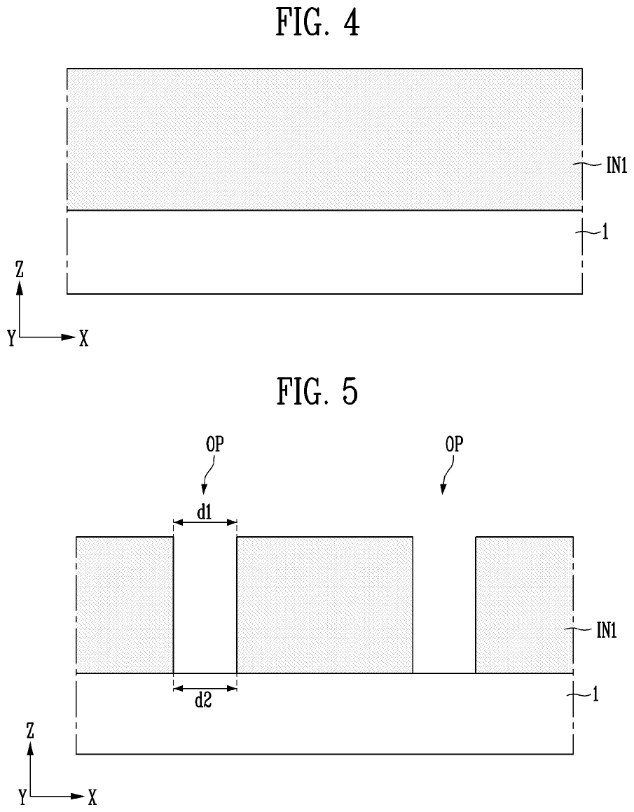

FIGS. 4 to 12 are schematic cross-sectional views for each process step of a method of manufacturing a light emitting element according to an embodiment. FIGS. 4 to 12 show a method of manufacturing the light emitting element LD shown in FIG. 1. Hereinafter, substantially the same components as those in FIG. 1 are denoted by the same reference numerals, and detailed reference numerals are omitted for descriptive convenience.

Referring to FIG. 4, the first insulating layer IN1 may be formed on a stack substrate 1. The stack substrate 1 may include a sapphire substrate and a transparent substrate such as glass. However, embodiments are not limited thereto, and may be formed of a conductive substrate such as GaN, SiC, ZnO, Si, GaP, and GaAs. Hereinafter, a case where the stack substrate 1 is the sapphire substrate is described as an example.

The first insulating layer IN1 may be formed of at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ), but embodiments are not limited thereto.

Referring to FIG. 5, the opening OP may be formed by etching the first insulating layer IN1. A first diameter d1 of an end portion (or a first end portion) of the opening OP and a second diameter d2 of another end portion (or a second end portion) may be the same as each other, but embodiments are not limited thereto.

Referring to FIG. 6, the first semiconductor layer 11, the active layer 12, and/or the second semiconductor layer 13 may be formed in the opening OP of the first insulating layer IN1. For example, the second semiconductor layer 13 may be formed on the stack substrate 1, and then the active layer 12 and the first semiconductor layer 11 may be sequentially formed. For example, the first semiconductor layer 11 may be formed at the end portion (or the first end portion) of the opening OP, and the second semiconductor layer 13 may be formed at another end portion (or the second end portion) of the opening OP.

The first semiconductor layer 11, the active layer 12, and/or the second semiconductor layer 13 may be formed by growing a seed crystal by an epitaxial method/process. According to an embodiment, the first semiconductor layer 11, the active layer 12, and/or the second semiconductor layer 13 may be formed by electron beam deposition, physical vapor deposition (PVD), chemical vapor deposition (CVD), plasma laser deposition (PLD), dual-type thermal evaporation, sputtering, and metal organic chemical vapor deposition (MOCVD), and may be formed by the MOCVD, but embodiments are not limited thereto.

According to an embodiment, a buffer layer may be formed between the stack substrate 1 and the second semiconductor layer 13. The buffer layer may function to reduce a lattice constant difference between the stack substrate 1 and the second semiconductor layer 13. For example, the buffer layer may include an undoped semiconductor. The buffer layer and the second semiconductor layer 13 may include substantially the same material such as a material which is not doped with an n-type or a p-type. In an embodiment, the buffer layer may be at least one of undoped InAlGaN, GaN, AlGaN, InGaN, or AlN, but embodiments are not limited thereto.

Referring to FIG. 7, the electrode layer 14 may be formed on the first semiconductor layer 11 and/or the first insulating layer IN1. The electrode layer 14 may be formed on the entire surface of the stack substrate 1. The electrode layer 14 may be formed of a transparent metal or a transparent metal oxide.

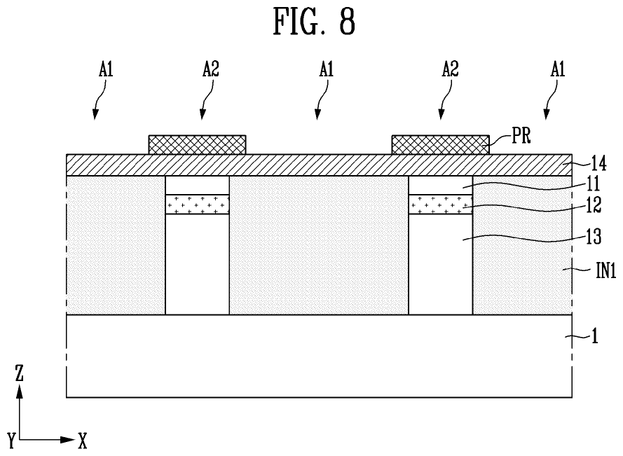

Referring to FIG. 8, a photoresist pattern layer PR may be formed (e.g., partially formed) in a second area A2. The photoresist pattern layer PR may be formed (e.g., partially formed) to overlap the opening OP (or the first semiconductor layer 11, the active layer 12, and the second semiconductor layer 13) of the first insulating layer IN1 described above in the third direction (e.g., Z-axis direction). The photoresist pattern layer PR may overlap (e.g., partially overlap) the first insulating layer IN1 surrounding the first semiconductor layer 11, the active layer 12, and the second semiconductor layer 13 in the third direction (e.g., Z-axis direction). For example, the first insulating layer IN1 overlapping the photoresist pattern layer PR may not be etched. Accordingly, since the first insulating layer IN1 overlapping the photoresist pattern layer PR protects the first semiconductor layer 11, the active layer 12, and/or the second semiconductor layer 13 in an etching process to be described below, the surface defect may be minimized, and thus the lifespan and the light emission efficiency of the light emitting elements LD may be improved.

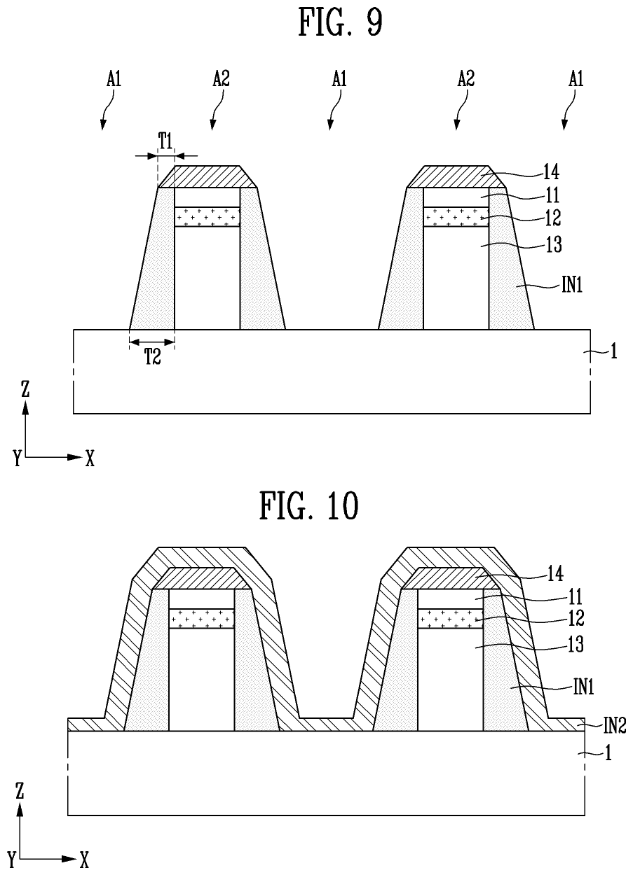

Referring to FIG. 9, the electrode layer 14 and/or the first insulating layer IN1 in a first area A1 may be etched (e.g., partially etched). For example, the electrode layer 14 and the first insulating layer IN1 may be simultaneously etched in the same process, but embodiments are not limited thereto.

In a process in which the first insulating layer IN1 is etched, the first thickness T1 of the first insulating layer IN1 surrounding the first semiconductor layer 11 may be formed differently from the second thickness T2 of the second insulating layer IN2 surrounding the second semiconductor layer 13. For example, the first thickness T1 of the first insulating layer IN1 surrounding the first semiconductor layer 11 may be formed to be thinner than the second thickness T2 of the second insulating layer IN2 surrounding the second semiconductor layer 13. As described above, in case that the first thickness T1 and the second thickness T2 of the first insulating layer IN1 are formed differently, the cross section of the light emitting element LD may be formed in a trapezoidal shape. Accordingly, in a step of aligning the light emitting clements LD, the light emitting elements LD may be readily biased and aligned by a center of gravity of the light emitting element LD. For example, in case that the reflective layer is formed on a side surface of the light emitting element LD, since the reflective layer is formed in an inclined shape, the light output efficiency by the reflective layer may be increased or improved.

In a process in which the electrode layer 14 is etched, a cross section of the electrode layer 14 may be formed in a trapezoidal shape. For example, a surface of the electrode layer 14 may be narrower than another surface of the electrode layer 14. However, embodiments are not limited thereto, and a surface and another surface of the electrode layer 14 may be formed identically.

Referring to FIG. 10, the second insulating layer IN2 may be formed on the first insulating layer IN1 and/or the electrode layer 14. The second insulating layer IN2 may be formed on the entire surface of the stack substrate 1.

The second insulating layer IN2 may be formed of at least one of silicon oxide (SiOₓ). silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ), but embodiments are not limited thereto.

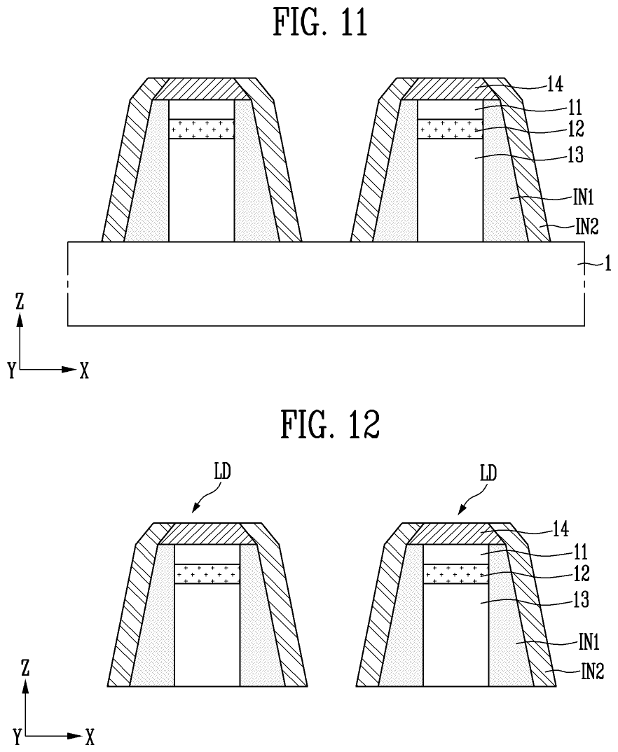

Referring to FIG. 11, the second insulating layer IN2 may be etched (e.g., partially etched). For example, an upper surface of the electrode layer 14 may be exposed by etching the second insulating layer IN2 covering the upper surface of the electrode layer 14. The second insulating layer IN2 may cover a side surface of the first insulating layer IN1 and/or the electrode layer 14.

Referring to FIG. 12, the light emitting elements LD shown in FIG. 1 may be manufactured by separating the second semiconductor layer 13 from the stack substrate 1. In accordance with the method of manufacturing the light emitting element LD according to the above-described embodiment, the light emitting element LD may be formed by etching (e.g., partially etching) the first insulating layer IN1 after forming the first semiconductor layer 11, the active layer 12, and/or the second semiconductor layer 13 in the opening OP of the first insulating layer IN1. Therefore, the surface defect may be minimized, and thus the lifespan and the light emission efficiency of the light emitting elements LD may be improved. For example, as the first thickness T1 and the second thickness T2 of the first insulating layer IN1 are formed differently in a process of etching the first insulating layer IN1, the cross section of the light emitting element LD may be formed in a trapezoidal shape. Accordingly, the light emitting element LD may be biased and aligned by the center of gravity in a step of aligning the light emitting element LD, an alignment degree may be improved.

Another embodiment is described as below. In the following embodiment, the same configuration as that previously described is denoted by the same reference numeral, and an overlapping description is omitted or simplified for descriptive convenience.

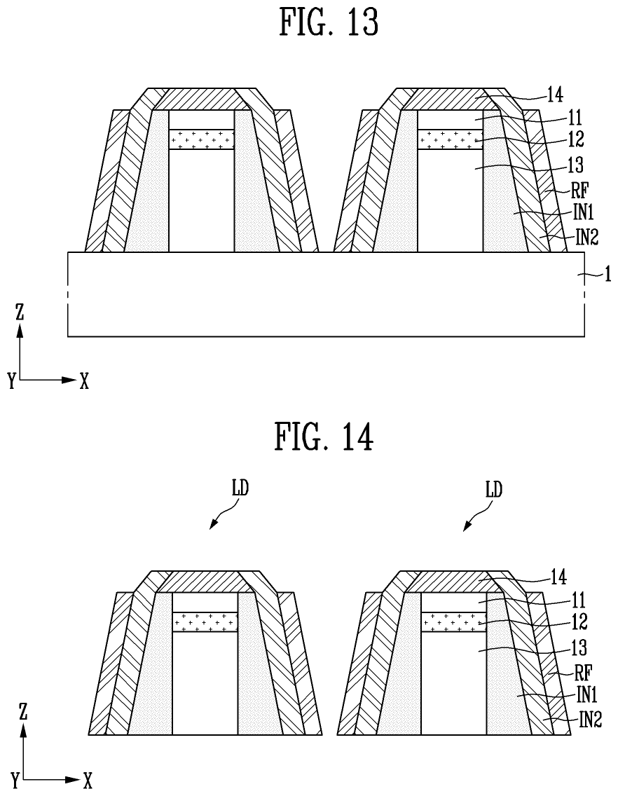

FIGS. 13 and 14 are schematic cross-sectional views for each process step of a method of manufacturing a light emitting element according to an embodiment. FIGS. 13 and 14 show a method of manufacturing the light emitting element LD shown in FIG. 3. Hereinafter, substantially the same components as those in FIG. 3 are denoted by the same reference numerals, and detailed reference numerals are omitted for descriptive convenience.

Referring to FIG. 13, a reflective layer RF may be formed on the second insulating layer IN2. Since a process of forming up to the second insulating layer IN2 is described with reference to FIGS. 4 to 11, an overlapping content is omitted for descriptive convenience.

After the reflective layer RF is formed on the entire surface of the stack substrate 1. the reflective layer RF may be etched (e.g., partially etched) to expose the electrode layer 14. In a process of etching the electrode layer 14, the second insulating layer IN2 surrounding the electrode layer 14 may be exposed. A material of the reflective layer RF is not limited and may be formed of various reflective materials.

Referring to FIG. 14, the light emitting elements LD shown in FIG. 3 may be manufactured by separating the second semiconductor layer 13 from the stack substrate 1. In accordance with the method of manufacturing the light emitting element LD according to the above-described embodiment, as the first thickness T1 and the second thickness T2 of the first insulating layer IN1 are formed differently, the cross section of the light emitting element LD may be formed in a trapezoidal shape. Therefore, since the reflective layer RF is formed an inclined shape, light output efficiency by the reflective layer RF may be increased or improved.

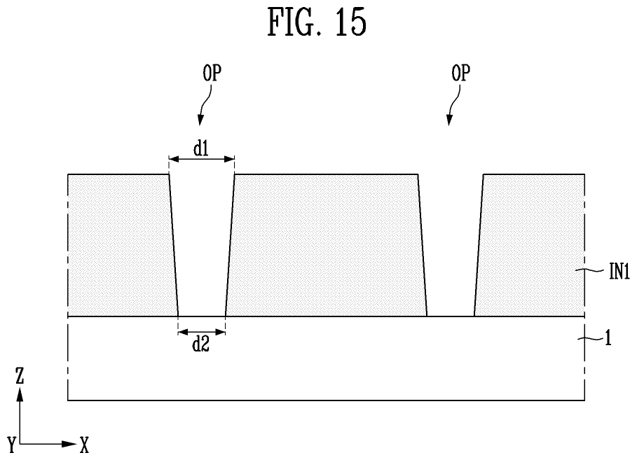

FIGS. 15 to 22 are schematic cross-sectional views for each process step of a method of manufacturing a light emitting element according to an embodiment. FIGS. 15 to 22 show a method of manufacturing the light emitting element LD shown in FIG. 2. Hereinafter, substantially the same components as those in FIG. 2 are denoted by the same reference numerals, and detailed reference numerals are omitted for descriptive convenience.

Referring to FIG. 15, the opening OP may be formed by etching the first insulating layer IN1. The first diameter d1 of the end portion (or the first end portion) of the opening OP may be different from the second diameter d2 of another end portion (or the second end portion). For example, the first diameter d1 of the end portion (or the first end portion) of the opening OP may be greater than the second diameter d2 of another end portion (or the second end portion), but embodiments are not limited thereto.

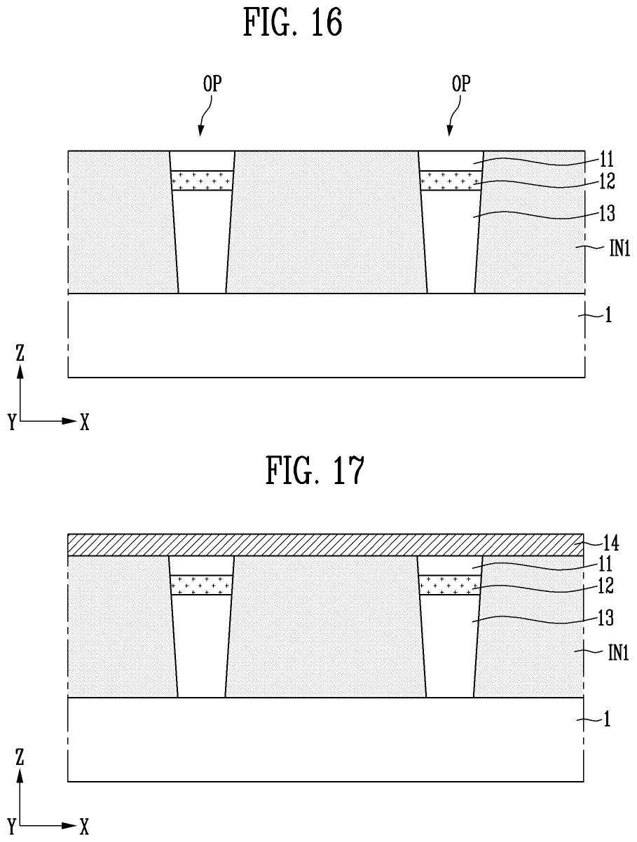

Referring to FIG. 16, the first semiconductor layer 11, the active layer 12, and/or the second semiconductor layer 13 may be formed in the opening OP of the first insulating layer IN1. For example, the second semiconductor layer 13 may be first formed on the stack substrate 1, and then the active layer 12 and the first semiconductor layer 11 may be sequentially formed. For example, the first semiconductor layer 11 may be formed at the end portion (or the first end portion) of the opening OP, and the second semiconductor layer 13 may be formed at another end portion (or the second end portion) of the opening OP.

The first semiconductor layer 11, the active layer 12, and/or the second semiconductor layer 13 may be formed by growing a seed crystal by an epitaxial method/process. Since a detailed description thereof is described with reference to FIG. 6, a redundant content is omitted for descriptive convenience.

Referring to FIG. 17, the electrode layer 14 may be formed on the first semiconductor layer 11 and/or the first insulating layer IN1. The electrode layer 14 may be formed on the entire surface of the stack substrate 1. The electrode layer 14 may be formed of a transparent metal or a transparent metal oxide.

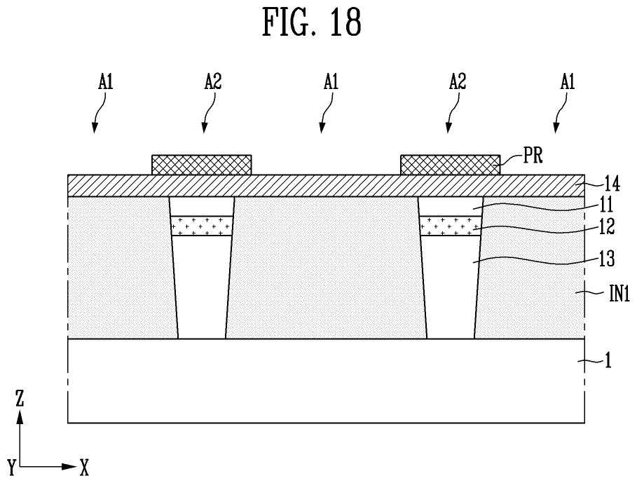

Referring to FIG. 18, the photoresist pattern layer PR may be formed (e.g., partially formed) in the second area A2. The photoresist pattern layer PR may be formed (e.g., partially formed) to overlap the opening OP (or the first semiconductor layer 11, the active layer 12, and the second semiconductor layer 13) of the first insulating layer IN1 described above in the third direction (e.g., Z-axis direction). The photoresist pattern layer PR may overlap (e.g., partially overlap) the first insulating layer IN1 surrounding the first semiconductor layer 11, the active layer 12, and the second semiconductor layer 13 in the third direction (e.g., Z-axis direction). For example, the first insulating layer IN1 overlapping the photoresist pattern layer PR may not be etched. Accordingly, since the first insulating layer IN1 overlapping the photoresist pattern layer PR protects the first semiconductor layer 11, the active layer 12, and/or the second semiconductor layer 13 in the etching process to be described below, the surface defect may be minimized, and thus the lifespan and the light emission efficiency of the light emitting elements LD may be improved.

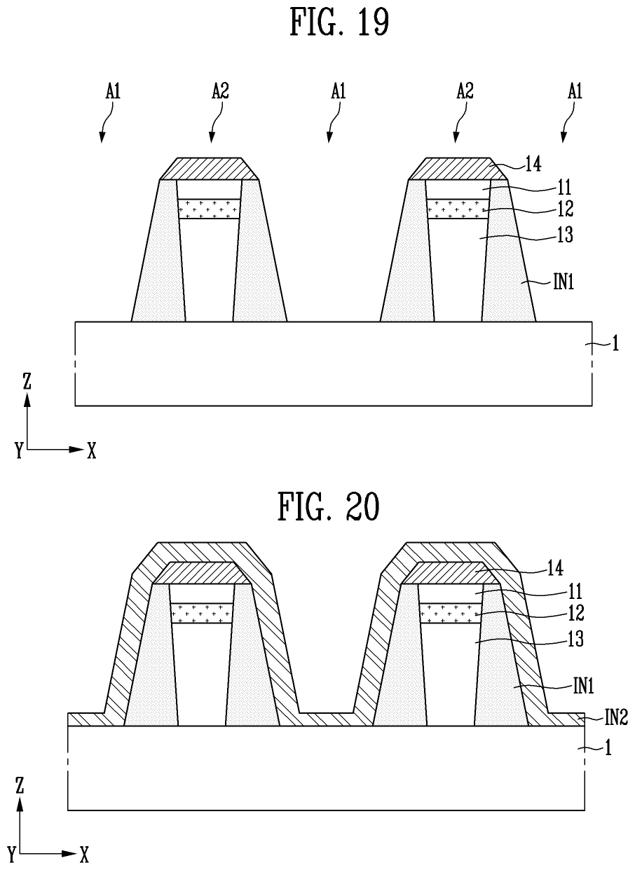

Referring to FIG. 19, the electrode layer 14 and/or the first insulating layer IN1 in the first area A1 may be etched (e.g., partially etched). For example, the electrode layer 14 and the first insulating layer IN1 may be simultaneously etched in the same process, but embodiments are not limited thereto.

In the process in which the first insulating layer IN1 is etched, the first thickness T1 of the first insulating layer IN1 surrounding the first semiconductor layer 11 may be formed differently from the second thickness T2 of the second insulating layer IN2 surrounding the second semiconductor layer 13. For example, the first thickness T1 of the first insulating layer IN1 surrounding the first semiconductor layer 11 may be formed to be thinner than the second thickness T2 of the second insulating layer IN2 surrounding the second semiconductor layer 13. As described above, in case that the first thickness T1 and the second thickness T2 of the first insulating layer IN1 are formed differently, the cross section of the light emitting element LD may be formed in a trapezoidal shape. Accordingly, in the step of aligning the light emitting elements LD, the light emitting elements LD may be biased and aligned by the center of gravity. For example, in case that the reflective layer is formed on the side surface of the light emitting element LD, since the reflective layer is formed in an inclined shape, the light output efficiency by the reflective layer may be increased or improved as described above.

In the process in which the electrode layer 14 is etched, the cross section of the electrode layer 14 may be formed in a trapezoidal shape. For example, the surface of the electrode layer 14 may be narrower than another surface of the electrode layer 14. However, embodiments are not limited thereto, and the surface and another surface of the electrode layer 14 may be formed identically.

Referring to FIG. 20, the second insulating layer IN2 may be formed on the first insulating layer IN1 and/or the electrode layer 14. The second insulating layer IN2 may be formed on the entire surface of the stack substrate 1.

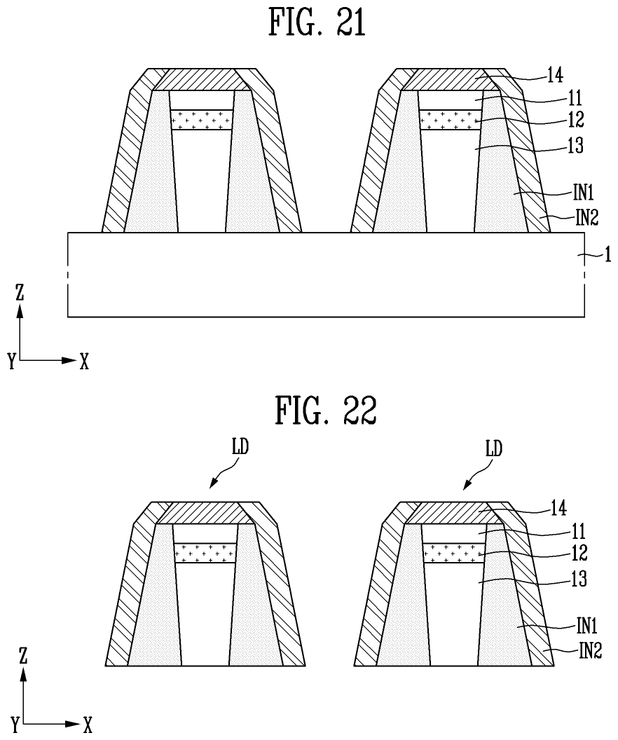

Referring to FIG. 21, the second insulating layer IN2 may be etched (e.g., partially etched). For example, an upper surface of the electrode layer 14 may be exposed by etching the second insulating layer IN2 covering the upper surface of the electrode layer 14. The second insulating layer IN2 may cover the side surface of the first insulating layer IN1 and the electrode layer 14.

Referring to FIG. 22, the light emitting elements LD shown in FIG. 2 may be manufactured by separating the second semiconductor layer 13 from the stack substrate 1. In accordance with the method of manufacturing the light emitting element LD according to the above-described embodiment, the light emitting element LD may be formed by etching (e.g., partially etching) the first insulating layer IN1 after forming the first semiconductor layer 11. the active layer 12, and/or the second semiconductor layer 13 in the opening OP of the first insulating layer IN1. Therefore, the surface defect may be minimized, and thus the lifespan and the light emission efficiency of the light emitting elements LD may be improved. For example, as the first thickness T1 and the second thickness T2 of the first insulating layer IN1 are formed differently in the process of etching the first insulating layer IN1, the cross section of the light emitting element LD may be formed in a trapezoidal shape. Accordingly, the light emitting element LD may be biased and aligned by the center of gravity in the step of aligning the light emitting element LD, the alignment degree may be improved as described above.

A display device including the light emitting element according to the above-described embodiments is described as below.

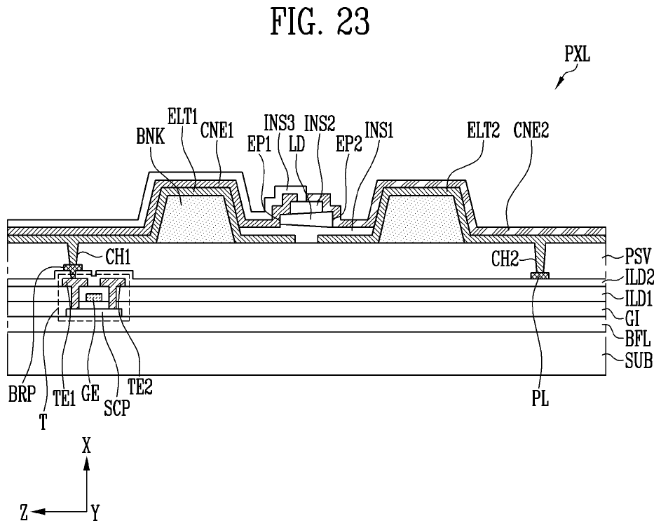

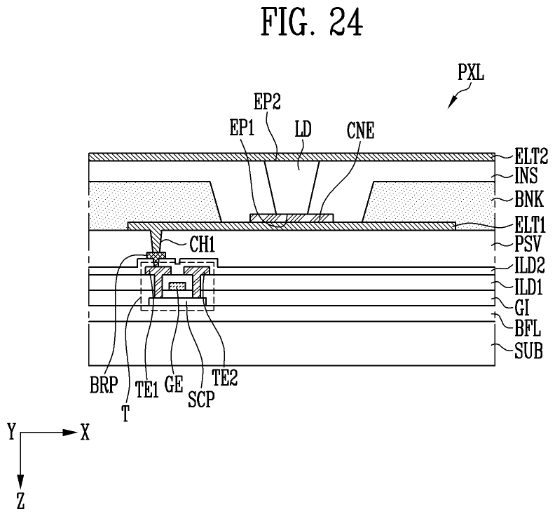

FIGS. 23 and 24 are schematic cross-sectional views illustrating a display device according to an embodiment. FIGS. 23 and 24 are schematic cross-sectional views illustrating the display device including the light emitting element LD described with reference to FIGS. 1 to 22, and show the display device based on pixels PXL included in the display device. Each of FIGS. 23 and 24 schematically shows a structure of each pixel PXL based on one light emitting element LD, and shows a transistor T connected to a first electrode ELT1 among various circuit elements. For example, a structure, a position of each layer, and/or the like of the transistor T are/is not limited to the embodiment shown in FIGS. 23 and 24 and may be variously changed according to an embodiment.

Referring to FIG. 23, the pixel PXL and the display device including the the pixel PXL may include a substrate SUB, the transistor T, first and second electrodes ELT1 and ELT2, the light emitting elements LD, and first and second connection electrodes CNE1 and CNE2.

The substrate SUB may be a base member, and may be a rigid or flexible substrate or film. For example, the substrate SUB may be a rigid substrate formed of glass or tempered glass, a flexible substrate (or a thin film) of a plastic or metal material, or an insulating layer of at least one layer. A material and/or a material property of the substrate SUB are/is not limited thereto. In an embodiment, the substrate SUB may be substantially transparent. Here, “substantially transparent” may mean that light may be transmitted at a certain transmittance or more. In another example, the substrate SUB may be translucent or opaque. The substrate SUB may include a reflective material according to an embodiment.

A buffer layer BFL may be disposed on the substrate SUB. The buffer layer BFL may prevent diffusion of an impurity into each circuit element. The buffer layer BFL may be formed as a single layer, but may be formed as multiple layers of at least two or more layers. In case that the buffer layer BFL is formed as multiple layers, each layer may be formed of the same material or may be formed of different materials. Various circuit elements such as the transistors T and various lines connected to the circuit elements may be disposed on the buffer layer BFL. In another example, the buffer layer BFL may be omitted.

Each transistor T may include a semiconductor pattern layer SCP, a gate electrode GE, and first and second transistor electrodes TE1 and TE2. For example, in FIG. 23, an embodiment in which the transistor T may include the first and second transistor electrodes TE1 and TE2 formed separately from the semiconductor pattern layer SCP is shown, but embodiments are not limited thereto. For example, in another example, the first transistor electrode TE1 and/or the second transistor electrode TE2 provided in at least one transistor T may be integral with each semiconductor pattern layer SCP.

The semiconductor pattern layer SCP may be disposed on the buffer layer BFL. For example, the semiconductor pattern layer SCP may be disposed between the substrate SUB on which the buffer layer BFL is formed and a gate insulating layer GI. The semiconductor pattern layer SCP may include a first area that is in contact with each first transistor electrode TE1, a second area that is in contact with each second transistor electrode TE2, and a channel area positioned between the first and second areas. According to an embodiment, one of the first and second areas may be a source area and the other may be a drain area.

According to an embodiment, the semiconductor pattern layer SCP may be a semiconductor pattern layer formed of polysilicon, amorphous silicon, oxide semiconductor, or the like. The channel area of the semiconductor pattern layer SCP may be an intrinsic semiconductor as a semiconductor pattern layer that is not doped with an impurity, and each of the first and second areas of the semiconductor pattern layer SCP may be a semiconductor pattern layer doped with a certain impurity.

The gate insulating layer GI may be disposed on the semiconductor pattern layer SCP. For example, the gate insulating layer GI may be disposed between the semiconductor pattern layer SCP and the gate electrode GE. The gate insulating layer GI may be formed as a single layer or multiple layers, and may include various types of organic/inorganic insulating materials including silicon nitride (SiNₓ), silicon oxide (SiOₓ), or silicon oxynitride (SiOₓN_{y}).

The gate electrode GE may be disposed on the gate insulating layer GI. For example, the gate electrode GE may be disposed to overlap the semiconductor pattern layer SCP with the gate insulating layer GI interposed between the gate electrode GE and the semiconductor pattern layer SCP.

A first interlayer insulating layer ILD1 may be disposed on the gate electrode GE. For example, the first interlayer insulating layer ILD1 may be disposed between the gate electrode GE and the first and second transistor electrodes TE1 and TE2. The first interlayer insulating layer ILD1 may be formed as a single layer or multiple layers, and may include at least one inorganic insulating material and/or an organic insulating material. For example, the first interlayer insulating layer ILD1 may include various types of organic/inorganic insulating materials including silicon nitride (SiNₓ), silicon oxide (SiOₓ), silicon oxynitride (SiOₓN_{y}), or the like, and a configuration material of the first interlayer insulating layer ILD1 is not limited thereto.

The first and second transistor electrodes TEL and TE2 may be disposed on each semiconductor pattern layer SCP with at least one first interlayer insulating layer ILD1 interposed between each semiconductor pattern layer SCP and the first and second transistor electrodes TE1 and TE2. For example, the first and second transistor electrodes TE1 and TE2 may be formed on different end portions of the semiconductor pattern layer SCP with the gate insulating layer GI and the first interlayer insulating layer ILD1 interposed between the semiconductor pattern layer SCP and the first and second transistor electrodes TE1 and TE2. The first and second transistor electrodes TE1 and TE2 may be connected (e.g., electrically connected) to each semiconductor pattern layer SCP. For example, the first and second transistor electrodes TE1 and TE2 may be connected to the first and second areas of the semiconductor pattern layer SCP through respective contact holes passing through the gate insulating layer GI and the first interlayer insulating layer ILD1. According to an embodiment, one of the first and second transistor electrodes TE1 and TE2 may be a source electrode, and the other may be a drain electrode.

The transistor T may be connected to at least one pixel electrode. For example, the transistor T may be electrically connected to the first electrode ELT1 of a corresponding pixel PXL through a contact hole (for example, a first contact hole CH1) passing through a protective layer PSV, and/or a bridge pattern layer BRP.

A power line PL may be formed of a layer identical to or different from a layer of the gate electrode GE or the first and second transistor electrodes TE1 and TE2 of the transistors T. For example, the power line PL may be disposed on the second interlayer insulating layer ILD2 and may be at least partially covered by the protective layer PSV. The power line PL may be connected (e.g., electrically connected) to the second electrode ELT2 disposed on the protective layer PSV through a second contact hole CH2 passing through the protective layer PSV. However, a position and/or a structure of the power line PL may be changed variously.

The second interlayer insulating layer ILD2 may be disposed on the first interlayer insulating layer ILD1 and may cover the first and second transistor electrodes TE1 and TE2 positioned on the first interlayer insulating layer ILD1. The second interlayer insulating layer ILD2 may be formed as a single layer or multiple layers, and may include at least one inorganic insulating material and/or organic insulating material. For example, the second interlayer insulating layer ILD2 may include various types of organic/inorganic insulating materials including silicon nitride (SiNₓ), silicon oxide (SiOₓ), or silicon oxynitride (SiOₓN_{y}), but embodiments are not limited thereto.

A bridge pattern layer BRP and the power line PL for electrically connecting the transistor T and the first electrode ELT1 may be formed on the second interlayer insulating layer ILD2. However, the second interlayer insulating layer ILD2 may be omitted according to an embodiment.

The protective layer PSV may be disposed on circuit elements including the transistors T and/or lines including the power line PL. The protective layer PSV may be formed as a single layer or multiple layers, and may include at least one inorganic insulating material and/or organic insulating material. For example, the protective layer PSV may include at least an organic insulating layer and may function to substantially planarize a lower step.

A bank BNK protruding in the third direction (e.g., Z-axis direction) may be disposed on the protective layer PSV. The bank BNK may be formed in a separate or integral pattern.

The bank BNK may have various shapes according to an embodiment. In an embodiment, the bank BNK may be a bank structure having a positive taper structure. For example, the bank BNK may be formed to have an inclined surface inclined at a constant angle with respect to the substrate SUB as shown in FIG. 23. However, embodiments are not limited thereto, and the bank BNK may have a sidewall of a curved surface, a step shape, or the like. For example, the bank BNK may have a cross section of a semicircle shape, a semi-ellipse shape, or the like.

Electrodes and insulating layers disposed on the bank BNK may have a shape corresponding to the bank BNK. For example, the bank BNK may function as a reflective member that improves light output efficiency of the display device by guiding light emitted from the light emitting elements LD toward a front surface direction of the pixel PXL, e.g., the third direction (e.g., Z-axis direction) together with the first and second electrodes ELT1 and ELT2 formed on the bank BNK.

The bank BNK may include an insulating material including at least one inorganic material and/or organic material. For example, the bank BNK may include at least one layer of inorganic layer including various inorganic insulating materials such as silicon nitride (SiNₓ) or silicon oxide (SiOₓ). In another example, the bank BNK may be formed as an insulator of a single layer or multiple layers including at least one layer of organic insulating layer including various types of organic insulating material, a photoresist layer, and/or the like, or including organic/inorganic materials in combination. For example, a configuration material and/or a pattern shape of the bank BNK may be variously changed.

The first and second electrodes ELT1 and ELT2 may be disposed on the bank BNK. The first and second electrodes ELT1 and ELT2 may be formed to be spaced apart from each other. The first and second electrodes ELT1 and ELT2 may receive a first alignment signal (or a first alignment voltage) and a second alignment signal (or a second alignment voltage), respectively, in an alignment step of the light emitting elements LD. For example, any one of the first and second electrodes ELT1 and ELT2 may receive an alignment signal of an alternating current form, and the other of the first and second electrodes ELT1 and ELT2 may receive an alignment voltage (for example, a ground voltage) having a constant voltage level. Accordingly, an electric field may be formed between the first and second electrodes ELT1 and ELT2, and thus the light emitting elements LD supplied to each of the pixels PXL may be aligned.

The first electrode ELT1 may be connected (e.g., electrically connected) to the bridge pattern layer BRP through the first contact hole CH1 and may be connected (e.g., electrically connected) to the transistor T through the bridge pattern layer BRP. However, embodiments are not limited thereto, and the first electrode ELT1 may be connected (e.g., directly connected) to a certain power line or signal line.

The second electrode ELT2 may be connected (e.g., electrically connected) to the power line PL through the second contact hole CH2. However, embodiments are not limited thereto, and the second electrode ELT2 may be connected (e.g., directly connected) to a certain power line or signal line.

Each of the first and second electrodes ELT1 and ELT2 may include at least one conductive material. For example, each of the first and second electrodes ELT1 and ELT2 may include at least one conductive material such as at least one metal among various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and the like, an alloy including the same, a conductive oxide such as indium tin oxide (ITO), indium zinc oxide (IZO), indium tin zinc oxide (ITZO), zinc oxide (ZnO), aluminum zinc oxide (AZO), gallium zinc oxide (GZO), zinc tin oxide (ZTO), gallium tin oxide (GTO), or a fluorine tin oxide (FTO), and a conductive polymer such as PEDOT, but embodiments are not limited thereto. For example, each of the first and second electrodes ELT1 and ELT2 may include a reflective electrode layer including a reflective conductive material. The first and second electrodes ELT1 and ELT2 may selectively further include at least one of at least one layer of transparent electrode layer disposed on and/or under the reflective electrode layer, and at least one layer of conductive capping layer covering an upper portion of the reflective electrode layer and/or the transparent electrode layer.

A first insulation layer INS1 may be disposed on an area of the first and second electrodes ELT1 and ELT2. The first insulation layer INS1 may be formed as a single layer or multiple layers, and may include at least one inorganic insulating material and/or organic insulating material. For example, the first insulation layer INS1 may include various types of organic/inorganic insulating materials such as silicon nitride (SiNₓ), silicon oxide (SiOₓ), silicon oxynitride (SiOₓN_{y}), or aluminum oxide (AlOₓ).

The light emitting elements LD may be supplied and aligned between the first and second electrodes ELT1 and ELT2. The light emitting elements LD may be manufactured by the method of manufacturing the light emitting element described with reference to FIGS. 4 to 22.

The light emitting elements LD may be prepared in a form dispersed in a certain solution and supplied to an emission area of each of the pixels PXL through an inkjet printing method or the like. For example, the light emitting elements LD may be dispersed in a volatile solvent and provided to each emission area. At this time, in case that a certain voltage is supplied through the first and second electrodes ELT1 and ELT2 of each of the pixels PXL, an electric field may be formed between the first and second electrodes ELT1 and ELT2, and thus the light emitting elements LD may be aligned between the first and second electrodes ELT1 and ELT2. After the light emitting elements LD are aligned, the light emitting elements LD may be stably arranged between the first and second electrodes ELT1 and ELT2 by evaporating the solvent or removing the solvent in another method. For example, in FIG. 23, a single light emitting element LD disposed in each pixel PXL is shown, but each pixel PXL may include a plurality of light emitting elements LD provided between the first and second electrodes ELT1 and ELT2. Therefore, hereinafter, the disclosure is described under an assumption that the pixel PXL includes the plurality of light emitting elements LD.

A second insulation layer INS2 may be disposed on an area of the light emitting clements LD. For example, the second insulation layer INS2 may be formed on an area of each of the light emitting elements LD to expose the first and second end portions EP1 and EP2 of each of the light emitting elements LD. For example, the second insulation layer INS2 may be disposed on an upper portion of an area including a central area of each of the light emitting elements LD. In case that the second insulation layer INS2 is formed on the light emitting elements LD after the alignment of the light emitting elements LD is completed, the light emitting elements LD may be prevented from being separated from an aligned position.

The second insulation layer INS2 may be formed as a single layer or multiple layers, and may include at least one inorganic insulating material and/or organic insulating material. For example, the second insulation layer INS2 may include various types of organic/inorganic insulating materials such as silicon nitride (SiNₓ), silicon oxide (SiOₓ), and aluminum oxide (AlOₓ).

The first and second connection electrodes CNE1 and CNE2 may be disposed on both end portions, e.g., the first and second end portions EP1 and EP2 of the light emitting elements LD which are not covered by the second insulation layer INS2, respectively. In an embodiment, the first and second connection electrodes CNE1 and CNE2 may be sequentially formed on different layers on a surface of the substrate SUB as shown in FIG. 23. For example, a third insulation layer INS3 may be disposed between the first and second connection electrodes CNE1 and CNE2 formed of different conductive layers. However, embodiments are not limited thereto, and the first and second connection electrodes CNE1 and CNE2 may be formed of the same conductive layer.

The first and second connection electrodes CNE1 and CNE2 may be disposed on the first and second electrodes ELT1 and ELT2 to cover an exposed area of the respective first and second electrodes ELT1 and ELT2. For example, the first and second connection electrodes CNE1 and CNE2 may be disposed on at least one area of the respective first and second electrodes ELT1 and ELT2 to be connected (e.g., electrically connected) to the first and second electrodes ELT1 and ELT2 on or around the bank BNK. Accordingly, the first and second connection electrodes CNE1 and CNE2 may be connected (e.g., electrically connected) to the first and second electrodes ELT1 and ELT2, respectively. For example, the first electrode ELT1 may be connected (e.g., electrically connected) to the first end portion EP1 of the adjacent light emitting element LD through the first connection electrode CNE1. The second electrode ELT2 may be connected (e.g., electrically connected) to the second end portion EP2 of the adjacent light emitting element LD through the second connection electrode CNE2.

The first and second connection electrodes CNE1 and CNE2 may be formed of various transparent conductive materials. For example, the first and second connection electrodes CNE1 and CNE2 may include at least one of various transparent conductive materials including indium tin oxide (ITO), indium zinc oxide (IZO), indium tin zinc oxide (ITZO), zinc oxide (ZnO), aluminum zinc oxide (AZO), gallium zinc oxide (GZO), zinc tin oxide (ZTO), gallium tin oxide (GTO), or a fluorine tin oxide (FTO), and may be substantially transparent or translucent to have a certain transmittance. Accordingly, the light emitted from the light emitting element LD through the respective first and second end portions EP1 and EP2 may pass through the first and second connection electrodes CNE1 and CNE2 and may be emitted to the outside.

The third insulation layer INS3 may be disposed between the first connection electrode CNE1 and the second connection electrode CNE2. As described above, in case that the third insulation layer INS3 is formed between the first connection electrode CNE1 and the second connection electrode CNE2, the first and second connection electrodes CNE1 and CNE2 may be stably separated by the third insulation layer INS3, and thus electrical stability between the first and second end portions EP1 and EP2 of the light emitting elements LD may be ensured. Accordingly, a short circuit defect may be effectively prevented from occurring between the first and second end portions EP1 and EP2 of the light emitting elements LD. The third insulation layer INS3 may be formed as a single layer or multiple layers, and may include at least one inorganic insulating material and/or organic insulating material. For example, the third insulation layer INS3 may include various types of organic/inorganic insulating materials including silicon nitride (SiNₓ), silicon oxide (SiOₓ), and aluminum oxide (AlOₓ).

Referring to FIG. 24, the first electrode ELT1 may be disposed on the protective layer PSV. Since a detailed description of a lower member including the protective layer PSV is described with reference to FIG. 23, a redundant content is omitted for descriptive convenience.

The first electrode ELT1 may be connected (e.g., electrically connected) to the bridge pattern layer BRP through the first contact hole CHI and may be connected (e.g., electrically connected) to the transistor T through the bridge pattern layer BRP. However, embodiments are not limited thereto, and the first electrode ELT1 may be connected (e.g., directly connected) to a certain power line or signal line.

The first electrode ELT1 may include at least one conductive material. For example, the first electrode ELT1 may include at least one conductive material such as at least one metal among various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and the like, an alloy including the same, a conductive oxide such as indium tin oxide (ITO), indium zinc oxide (IZO), indium tin zinc oxide (ITZO), zinc oxide (ZnO), aluminum zinc oxide (AZO), gallium zinc oxide (GZO), zinc tin oxide (ZTO), gallium tin oxide (GTO), or a fluorine tin oxide (FTO), and a conductive polymer such as PEDOT, but embodiments are not limited thereto. According to an embodiment, the first electrode ELT1 may include a reflective electrode layer including a reflective conductive material.

The connection electrode CNE may be disposed on the first electrode ELT1. For example, the connection electrode CNE may be formed of a multiple layers of electrode. The connection electrode CNE may include a bonding metal bonded to the light emitting element LD. The connection electrode CNE may have conductivity by including at least one conductive material, and a configuration material thereof is not limited thereto. For example, the connection electrode CNE may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper (Cu), or another conductive material. According to an embodiment, the connection electrode CNE may include a reflective conductive material. For example, the connection electrode CNE may be formed of a metal layer including at least one of reflective metals including a metal having a high reflectance in a visible light wavelength band, for example, aluminum (Al), gold (Au), and silver (Ag). Accordingly, the light output efficiency of the pixels PXL may be increased or improved. In another example, the connection electrode CNE may be omitted.

The bank BNK may be disposed on the protective layer PSV and/or the first electrode ELT1. In an embodiment, the bank BNK may be formed to have a height (or thickness) equal to or lower than that of the light emitting elements LD. The height of the bank BNK may be set in consideration of a light output characteristic (for example, a divergence angle of light) of the light emitting elements LD, efficiency of a subsequent process, and/or the like, and may be variously changed according to an embodiment.

The bank BNK may include an insulating material including at least one inorganic material and/or organic material. For example, the bank BNK may include at least one layer of inorganic layer including various inorganic insulating materials such as silicon nitride (SiNₓ) or silicon oxide (SiOₓ). In another example, the bank BNK may be formed as an insulator of a single layer or multiple layers including at least one layer of organic insulating layer or the like including various types of organic insulating material, or including organic/inorganic materials in combination. For example, a configuration material and/or a pattern shape of the bank BNK may be variously changed. According to an embodiment, the bank BNK may include at least one light-blocking and/or reflective material. For example, the bank BNK may include at least one black matrix material, a color filter material of a specific color, and/or the like, and may include various other materials.

The light emitting element LD may be disposed on the first electrode ELT1 (or the connection electrode CNE). The light emitting element LD may be disposed on the first electrode ELT1 (or the connection electrode CNE) between the banks BNK. In an embodiment, the light emitting element LD may contact the connection electrode CNE and may be connected (e.g., electrically connected) to the first electrode ELT1 through the connection electrode CNE.

An insulating layer INS may be disposed on the bank BNK and/or the light emitting element LD. The insulating layer INS may at least partially cover the first electrode ELT1 and the connection electrode CNE exposed by the bank BNK. The insulating layer INS may surround the light emitting element LD disposed on (or bonded to) the first electrode ELT1 (or the connection electrode CNE). According to an embodiment, the insulating layer INS may include a low refractive index filler. The insulating layer INS may include at least one insulating material, and a material or a structure of the insulating layer INS is not limited thereto. For example, the insulating layer INS may include various types of inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The second electrode ELT2 may be disposed on the insulating layer INS. For example, adjacent pixels PXL may share a single second electrode ELT2. The second electrode ELT2 may be disposed on the second end portion EP2 of the light emitting element LD to be connected (e.g., electrically connected) to the second end portion EP2 of the light emitting element LD.

The second electrode ELT2 may have conductivity by including at least one conductive material. In an embodiment, the second electrode ELT2 may include a transparent conductive material. For example, the second electrode ELT2 may include at least one of various transparent conductive materials including indium tin oxide (ITO), indium zinc oxide (IZO), indium tin zinc oxide (ITZO), zinc oxide (ZnO), aluminum zinc oxide (AZO), gallium zinc oxide (GZO), zinc tin oxide (ZTO), gallium tin oxide (GTO), or a fluorine tin oxide (FTO), and may be substantially transparent or translucent to have a certain transmittance. Accordingly, the light emitted from the light emitting element LD through the second end portion EP2 may pass through the second electrode ELT2 and may be emitted to the outside.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A light emitting element comprising:
a first semiconductor layer;
a second semiconductor layer;
an active layer between the first semiconductor layer and the second semiconductor layer; and
a first insulating layer surrounding the first semiconductor layer, the second semiconductor layer, and the active layer,
wherein a first thickness of the first insulating layer surrounding the first semiconductor layer is different from a second thickness of the first insulating layer surrounding the second semiconductor layer.

2. The light emitting element of claim 1, wherein the first thickness of the first insulating layer is thinner than the second thickness of the first insulating layer.

3. The light emitting element of claim 2, wherein a diameter of the first semiconductor layer and a diameter of the second semiconductor layer are same as each other.

4. The light emitting element of claim 2, wherein a diameter of the first semiconductor layer is greater than a diameter of the second semiconductor layer.

5. The light emitting element of claim 1, further comprising:
a second insulating layer surrounding the first insulating layer.

6. The light emitting element of claim 5, further comprising:
an electrode layer disposed on the first semiconductor layer and the first insulating layer.

7. The light emitting element of claim 6, wherein the second insulating layer surrounds a side surface of the electrode layer.

8. The light emitting element of claim 6, wherein the second insulating layer exposes the electrode layer and the second semiconductor layer.

9. The light emitting element of claim 5, further comprising:
a reflective layer disposed on the second insulating layer.

10. A method of manufacturing a light emitting element, the method comprising:
forming a first insulating layer on a stack substrate;
forming an opening by etching the first insulating layer;
forming a first semiconductor layer, an active layer, and a second semiconductor layer in the opening of the first insulating layer;
partially etching the first insulating layer in a first area; and
forming a second insulating layer surrounding the first insulating layer in a second area,
wherein in the etching of the first insulating layer in the first area, a thickness of the first insulating layer surrounding the first semiconductor layer is thinner than a thickness of the first insulating layer surrounding the second semiconductor layer.

11. The method of claim 10, further comprising:
forming an electrode layer on the first semiconductor layer and the first insulating layer.

12. The method of claim 11, further comprising:
etching the electrode layer in the first area.

13. The method of claim 12, wherein the electrode layer and the first insulating layer in the first area are simultaneously etched.

14. The method of claim 12, wherein the second insulating layer surrounds the electrode layer in the second area.

15. The method of claim 14, wherein a surface of the electrode layer is exposed by partially etching the second insulating layer.

16. The method of claim 10, wherein a diameter of a first end portion of the opening and a diameter of a second end portion of the opening are same as each other.

17. The method of claim 10, wherein a diameter of a first end portion of the opening is greater than a diameter of a second end portion of the opening.

18. The method of claim 17, wherein
the first semiconductor layer is formed at the first end portion of the opening, and
the second semiconductor layer is formed at the second end portion of the opening.

19. The method of claim 10, further comprising:
forming a reflective layer on the second insulating layer.

20. The method of claim 10, further comprising:
separating the second semiconductor layer from the stack substrate.
